(19) United States
(12) Patent Application Publication
(10) Pub. No.: US 2005/0024127 A1
(43) Pub. Date: Feb. 3, 2005

(54) Semiconductor device including reference voltage generation circuit attaining reduced current consumption during stand-by

(75) Inventor: Yuji Kihara, Hyogo (JP)

Correspondence Address: McDermott, Will & Emery LLP, 600 13th Street, N.W., Washington, DC, 20005-3096, US

(73) Assignee: RENESAS TECHNOLOGY CORP.

(21) Appl. No.: 10/901,103

(22) Filed: Jul. 29, 2004

(30) Foreign Application Priority Data
Jul. 31, 2003 (JP) 2003-284004

(51) Int. Cl. G11C 11/34

(52) U.S. Cl. 327/540

(57) ABSTRACT

During operation, a control signal attains H level, a conventional type first reference voltage generation circuit is activated, and the first reference voltage generation circuit generates a reference voltage. During stand-by, the control signal attains L level, and the first reference voltage generation circuit is inactivated, whereby a through current does not flow through the first reference voltage generation circuit. Then, during stand-by, an internal voltage generation circuit is supplied with the reference voltage generated by a second reference voltage generation circuit including a resistance division circuit constituted of first to third resistors each having a high resistance value of T (tera) Ω order, in which a through current is extremely small.

### BACKGROUND OF THE INVENTION

1. Field of the Invention

The present invention relates to a semiconductor device, and more particularly to a semiconductor device including a reference voltage generation circuit generating a reference voltage.

2. Description of the Background Art

As a semiconductor process technology develops, a semiconductor element has increasingly been reduced in size in recent days. Accordingly, a voltage that can be applied to the semiconductor element has been lowered. An applied power supply voltage has been lowered also in order to suppress increase in power consumption due to increase in the number of integrated semiconductor elements.

On the other hand, a semiconductor device is incorporated and used in electronics along with various other devices, and an external power supply voltage is not necessarily low. In general, a semiconductor device contains an internal voltage generation circuit. Therefore, a power supply voltage required by electronics on which the semiconductor device is mounted is used outside the semiconductor device, whereas the internal power supply voltage lower than the external power supply voltage, which is generated by the internal voltage generation circuit, is used inside the semiconductor device.

In order to generate a desired internal power supply voltage in the semiconductor device, a desired voltage should be generated as a reference voltage. A known example of the reference voltage generation circuit generating the reference voltage is a threshold voltage reference type circuit. The reference voltage generation circuit is constituted of two P-channel MOS transistors of the same size constituting a current mirror circuit, two N-channel MOS transistors having a threshold voltage of Vth, and a resistor element. A stable bias current I based on threshold voltage Vth flows through the reference voltage generation circuit, whereby a stable reference voltage Vref can be generated. In past few years, the electronics have further been reduced in size so as to achieve improved portability. As such, it is essential for the semiconductor device mounted on such electronics to achieve reduced power consumption. Japanese Patent Laying-Open No. 2002-150772 discloses a technology to reduce current consumption by reducing a stand-by current in a semiconductor memory device including a reference voltage generation circuit, in that a prescribed reference voltage Va is generated during a normal operation and a reference voltage Vb lower than reference voltage Va is generated during stand-by.

A through current flows through the reference voltage generation circuit in order to generate a reference voltage. Though bias current I based on threshold voltage Vth flows through the reference voltage generation circuit of threshold voltage reference type as a through current, the through current can cause a problem in a device requiring a low current characteristic during stand-by.

For example, an SRAM (Static Random Access Memory) does not require a refreshing operation necessary in a DRAM (Dynamic Random Access Memory). Therefore, if the SRAM is backed up by a battery during stand-by, the SRAM can implement a pseudo non-volatile semiconductor memory device. (Such an SRAM is also referred to as “LPSRAM (Low Power SRAM)”.) If the through current in the reference voltage generation circuit is large, however, the battery is immediately discharged during stand-by. In such a case, eventually, the data can be held only for a short time.

In a conventional reference voltage generation circuit represented by the threshold voltage reference type described above, the through current for generating the reference voltage is large. Accordingly, reduction in the stand-by current is a challenge in a semiconductor device such as an LPSRAM requiring a low current characteristic during stand-by.

The semiconductor memory device described in Japanese Patent Laying-Open No. 2002-150772 achieves reduction in the stand-by current by lowering the reference voltage during stand-by. Here, the reference voltage generation circuit itself includes two current mirror circuits through which a large through current constantly flows. Since the technology disclosed in this publication aims to lower the reference voltage during stand-by, this technology is inapplicable to a semiconductor device in which a reference voltage the same as that in the normal operation should be maintained also during stand-by.

### SUMMARY OF THE INVENTION

The present invention was made to solve the above-described problems. An object of the present invention is to provide a semiconductor device including a reference voltage generation circuit attaining reduced current consumption during stand-by.

According to the present invention, a semiconductor device includes a first reference voltage generation circuit inactivated during stand-by and generating a prescribed reference voltage and outputting the generated reference voltage to a reference voltage line during operation, i.e., during non stand-by; and a second reference voltage generation circuit generating the reference voltage during stand-by using a through current smaller than in the first reference voltage generation circuit and outputting the generated reference voltage to the reference voltage line.

According to the semiconductor device of the present invention, during operation, a conventional type first reference voltage generation circuit is employed. On the other hand, during stand-by, the first reference voltage generation circuit is inactivated, and the second reference voltage generation circuit in which a through current is smaller than in the first reference voltage generation circuit is employed. Therefore, current consumption during stand-by is reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a configuration of a main portion of a semiconductor device in a first embodiment of the present invention.

FIG. 2 is a circuit diagram showing a configuration of a main portion of a semiconductor device in a second embodiment of the present invention.

FIG. 3 is a circuit diagram showing a configuration of a memory cell in an SRAM contained in an internal circuit shown in FIG. 2.

FIG. 4 is a circuit diagram showing a configuration of a memory cell in a memory unit contained in an internal circuit of a semiconductor device in a third embodiment.

FIG. 5 is a circuit diagram showing a configuration of a main portion of a semiconductor device in a fourth embodiment of the present invention.

FIG. 6 is a circuit diagram showing a configuration of a main portion of a semiconductor device in a fifth embodiment of the present invention.

### DESCRIPTION OF THE PREFERRED EMBODIMENTS

In the following, embodiments of the present invention will be described in detail with reference to the figures. It is noted that the same reference characters refer to the same or corresponding components in the figures.

First Embodiment

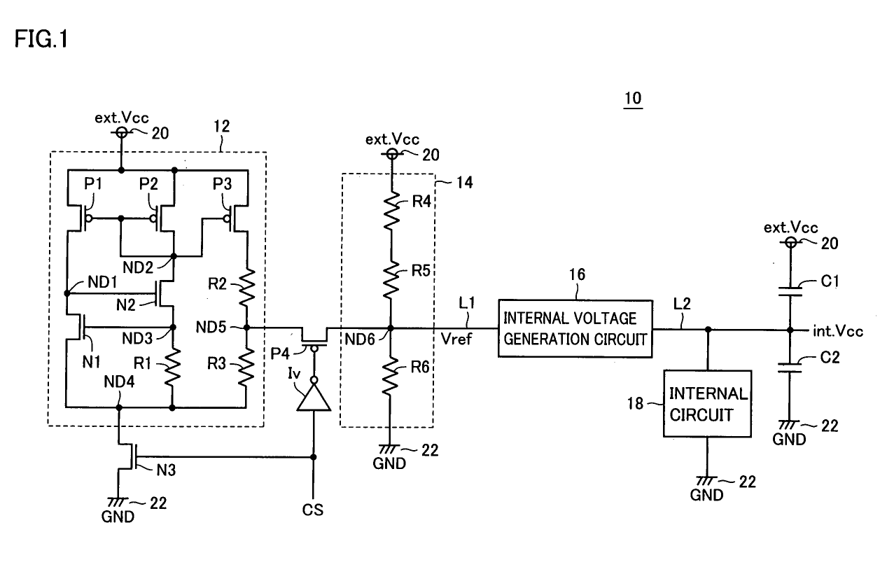

FIG. 1 is a circuit diagram showing a configuration of a main portion of a semiconductor device 10 in a first embodiment of the present invention.

Referring to FIG. 1, semiconductor device 10 includes a first reference voltage generation circuit 12, a second reference voltage generation circuit 14, an N-channel MOS transistor N3, a P-channel MOS transistor P4, an inverter Iv, an internal voltage generation circuit 16, an internal circuit 18, a reference voltage line L1, an internal power supply line L2, and capacitors C1, C2.

First reference voltage generation circuit 12 includes P-channel MOS transistors P1 to P3, N-channel MOS transistors N1, N2, and resistors R1 to R3. Second reference voltage generation circuit 14 includes resistors R4 to R6.

First reference voltage generation circuit 12 is a voltage generation circuit of threshold voltage reference type. P-channel MOS transistor P1 is connected between a power supply node 20 to which an external power supply voltage ext.Vcc is applied and a node ND1, and has the gate connected to a node ND2. P-channel MOS transistor P2 is connected between power supply node 20 and node ND2, and has the gate connected to node ND2.

N-channel MOS transistor N1 is connected between node ND1 and a node ND4, and has the gate connected to a node ND3. N-channel MOS transistor N2 is connected between node ND2 and node ND3, and has the gate connected to node ND 1. P-channel MOS transistor P3 is connected between power supply node 20 and resistor R2, and has the gate connected to node ND2. Resistor R1 is connected between node ND3 and node ND4, resistor R2 is connected between P-channel MOS transistor P3 and a node ND5, and resistor R3 is connected between node ND5 and node ND4.

In first reference voltage generation circuit 12, P-channel MOS transistors P1, P2 are of the same size and constitute a current mirror circuit. Then, feedback from N-channel MOS transistor N2 and P-channel MOS transistors P1, P2 attempts to feed a current of a value the same as that of current I flowing through resistor R1 to N-channel MOS transistor N1, so that a stable reference voltage is generated.

P-channel MOS transistor P3 and resistors R2, R3 are provided in order to stabilize an operation. When P-channel MOS transistor P3 receives a gate voltage of a value the same as that for P-channel MOS transistor P2 at its gate and a constant current flows through a load circuit constituted of resistors R2, R3, further stabilized reference voltage Vref is generated at node ND5.

N-channel MOS transistor N3 is provided in order to activate/inactivate first reference voltage generation circuit 12. N-channel MOS transistor N3 is connected between node ND4 of first reference voltage generation circuit 12 and a ground node 22 to which a ground voltage GND is applied, and receives a control signal CS at its gate. Here, control signal CS attains H (logic high) level during operation and attains L (logic low) level during stand-by.

Therefore, during operation, N-channel MOS transistor N3 turns ON, first reference voltage generation circuit 12 is activated, reference voltage Vref is generated at node ND5 of first reference voltage generation circuit 12, and a through current Ip1 flows through N-channel MOS transistor N3. On the other hand, during stand-by, N-channel MOS transistor N3 turns OFF, first reference voltage generation circuit 12 is inactivated, and through current Ip1 does not flow.

P-channel MOS transistor P4 is provided for electrical connection/disconnection of first reference voltage generation circuit 12 to/from reference voltage line L1. P-channel MOS transistor P4 is connected between node ND5 of first reference voltage generation circuit 12 and a node ND6 of second reference voltage generation circuit 14 descried later, and receives an output signal from inverter Iv at its gate. Inverter Iv outputs an inverted signal of control signal CS.

Second reference voltage generation circuit 14 is a voltage generation circuit of resistance division type. Resistor R4 is connected between power supply node 20 and resistor R5, and resistor R5 is connected between resistor R4 and node ND6. Resistor R6 is connected between node ND6 and ground node 22.

Resistors R4 to R6 are resistance elements composed of polysilicon and each having a resistance value of T (tera) Ω order. Each of resistors R4 to R6 has a resistance value theoretically calculated based on external power supply voltage ext.Vcc applied to power supply node 20, desired reference voltage Vref and a through current tolerable during stand-by.

In second reference voltage generation circuit 14, reference voltage Vref is generated at node ND6 by a resistance division circuit constituted of resistors R4 to R6. As the resistance values of resistors R4 to R6 are of the order of TΩ and very high, a through current Ip2 flowing from power supply node 20 to ground node 22 is extremely small.

Internal voltage generation circuit 16, which is one of internal operation circuits operating based on a value of reference voltage Vref, generates internal power supply voltage int.Vcc based on reference voltage Vref, and outputs the generated internal power supply voltage int.Vcc to internal power supply line L2.

Internal circuit 18 comprehensively represents circuits in semiconductor device 10 except for those shown in FIG. 1. Each circuit contained in internal circuit 18 operates by receiving internal power supply voltage int.Vcc from internal power supply line L2.

Capacitors C1, C2 are provided in order to stabilize internal power supply voltage int.Vcc. Capacitor C1 is connected between power supply node 20 and internal power supply line L2, while capacitor C2 is connected between internal power supply line L2 and ground node 22.

In the following, an operation of semiconductor device 10 will be described.

(1) During Operation

During operation, control signal CS attains H level, and N-channel MOS transistor N3 and P-channel MOS transistor P4 turn ON. Then, first reference voltage generation circuit 12 is activated, and reference voltage Vref generated by first reference voltage generation circuit 12 is output to reference voltage line L1. Through current Ip1 flows through first reference voltage generation circuit 12, of which magnitude is of approximately 0.5 to 1.0 μA (microampere).

On the other hand, though second reference voltage generation circuit 14 also outputs reference voltage Vref to reference voltage line L1, second reference voltage generation circuit 14 hardly affects an overall operation during operation of first reference voltage generation circuit 12, because second reference voltage generation circuit 14 has a high resistance value of the order of TΩ as described above.

Internal voltage generation circuit 16 generates internal power supply voltage int.Vcc based on reference voltage Vref generated mainly by first reference voltage generation circuit 12, and each circuit contained in internal circuit 18 operates by receiving internal power supply voltage int.Vcc.

(2) During Stand-By

During stand-by, control signal CS attains L level, and N-channel MOS transistor N3 and P-channel MOS transistor P4 turn OFF. Then, first reference voltage generation circuit 12 is inactivated, and through current Ip1 does not flow through first reference voltage generation circuit 12. In addition, first reference voltage generation circuit 12 is electrically disconnected from reference voltage line L1.

Therefore, reference voltage Vref generated by second reference voltage generation circuit 14 is supplied to internal voltage generation circuit 16. Then, internal voltage generation circuit 16 generates internal power supply voltage int.Vcc based on reference voltage Vref generated by second reference voltage generation circuit 14, and supplies the generated internal power supply voltage int.Vcc to internal circuit 18.

Here, as resistors R4 to R6 constituting second reference voltage generation circuit 14 have resistance values of the order of TΩ, through current Ip2 flowing through second reference voltage generation circuit 14 is of the order of p (pico) A to n (nano) A. This value is smaller than through current Ip1 flowing through first reference voltage generation circuit 12 during operation by not smaller than two orders of magnitude, that is, extremely low. Therefore, the low current characteristic during stand-by can be realized.

In the first embodiment, second reference voltage generation circuit 14 is always activated not only during stand-by but also during operation in which first reference voltage generation circuit 12 is activated. Therefore, when an operation mode makes a transition from an operation state to a stand-by state, there is no delay until second reference voltage generation circuit 14 is activated. In addition, the through current in second reference voltage generation circuit 14 is small, which means that a current drivability of second reference voltage generation circuit 14 is small, thereby suppressing abrupt fluctuation of reference voltage Vref As described above, as current consumption in second reference voltage generation circuit 14 is small, increase in current consumption will not be a problem even if second reference voltage generation circuit 14 is always activated.

On the other hand, when the operation mode makes a transition from the stand-by state to the operation state, lowering of reference voltage Vref until first reference voltage generation circuit 12 is activated is a concern. In addition, it is also a concern that an amount of current flowing through reference voltage line L1 abruptly increases in response to activation of first reference voltage generation circuit 12 and internal power supply voltage int.Vcc considerably fluctuates. Such fluctuation, however, is mitigated by capacitors C1, C2 connected to internal power supply line L2, so as to stabilize internal power supply voltage int.Vcc. Here, capacitors C1, C2 have a capacitance of the order of nF for peripheral circuits in a memory, for example.

As external power supply voltage ext.Vcc fluctuates to some degree within a tolerable range, reference voltage Vref directly reflects such fluctuation in second reference voltage generation circuit 14. During stand-by, however, it is not necessary to control the voltage as strictly as during operation. In other words, resistance division in second reference voltage generation circuit 14 should only be adjusted so long as reliability of the transistor receiving the voltage supply during stand-by is not deteriorated.

As described above, according to semiconductor device 10 in the first embodiment, first reference voltage generation circuit 12 of a conventional type is employed during operation, whereas during stand-by, first reference voltage generation circuit 12 is inactivated and second reference voltage generation circuit 14 in which a through current is smaller than in first reference voltage generation circuit 12 is employed. Current consumption during stand-by is thus reduced.

Second Embodiment

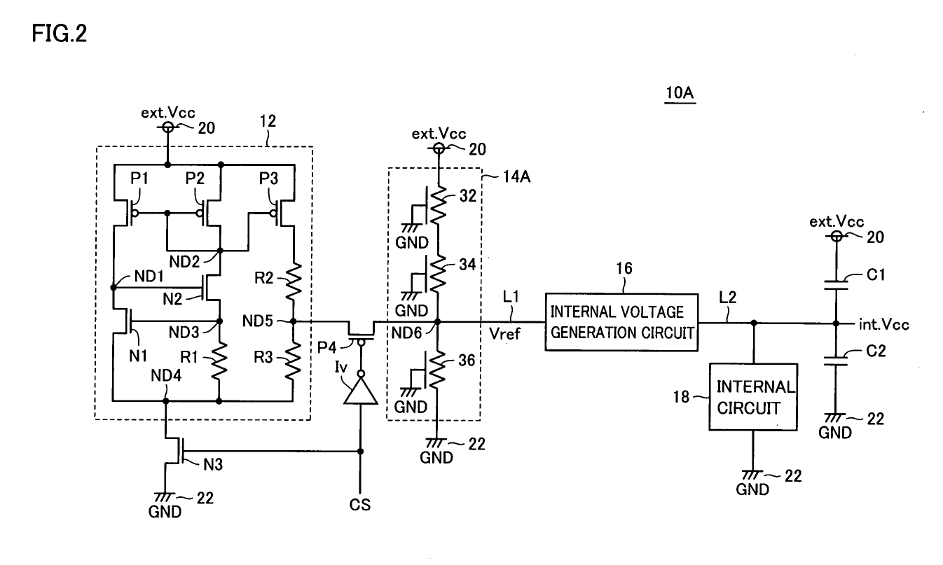

FIG. 2 is a circuit diagram showing a configuration of a main portion of a semiconductor device 10A in a second embodiment of the present invention.

Referring to FIG. 2, semiconductor device 10A includes a second reference voltage generation circuit 14A instead of second reference voltage generation circuit 14 in the configuration of semiconductor device 10 in the first embodiment. The configuration of semiconductor device 10A is otherwise the same as that of semiconductor device 10.

Second reference voltage generation circuit 14A includes P-channel thin film transistors (hereinafter, the thin film transistor is also referred to as “TFT (Thin Film Transistor)”) 32 to 36. P-channel TFT 32 is connected between power supply node 20 and P-channel TFT 34, and receives ground voltage GND at its gate. P-channel TFT 34 is connected between P-channel TFT 32 and node ND6, and receives ground voltage GND at its gate. P-channel TFT 36 is connected between node ND6 and ground node 22, and receives ground voltage GND at its gate.

Second reference voltage generation circuit 14A is also a voltage generation circuit of resistance division type. P-channel TFTs 32 to 36 are always turned ON, and have an ON resistance value of the order of G (giga) Ω. Each of P-channel TFTs 32 to 36 has an ON resistance value theoretically calculated based on external power supply voltage ext.Vcc applied to power supply node 20, desired reference voltage Vref and a through current tolerable during stand-by.

Semiconductor device 10A in the second embodiment operates in a manner similar to semiconductor device 10 in the first embodiment. As P-channel TFTs 32 to 36 constituting second reference voltage generation circuit 14A have an ON resistance value of the order of GΩ, through current Ip2 flowing through second reference voltage generation circuit 14A during stand-by is of the order of nA. This value is smaller than through current Ip1 flowing through first reference voltage generation circuit 12 during operation by not smaller than two orders of magnitude, that is, extremely low. Therefore, the low current characteristic during stand-by can be realized also according to semiconductor device 10A in the second embodiment.

If suppression of even the through current of the order of nA during stand-by is further desired, P-channel TFTs 32 to 36 in an OFF state may be used. In the OFF state, however, chargeability to reference voltage line L1 is poorer than in the ON state. Therefore, use of P-channel TFTs 32 to 36 in the ON state is more desirable in terms of resistance to voltage noise.

Internal circuit 18 in semiconductor device 10A includes a TFT load type SRAM.

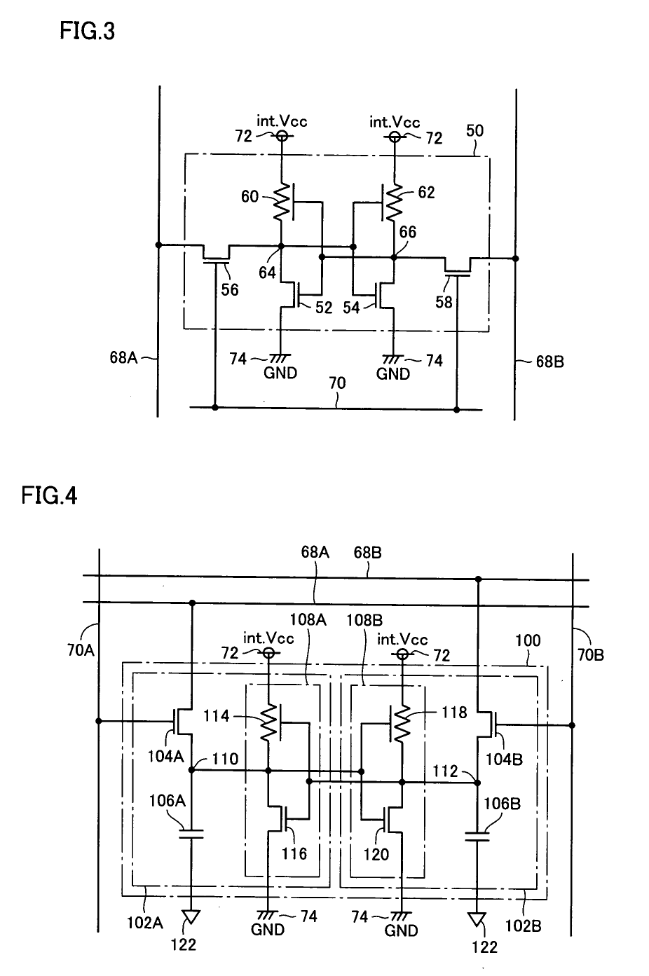

FIG. 3 is a circuit diagram showing a configuration of a memory cell in an SRAM contained in internal circuit 18 shown in FIG. 2.

Referring to FIG. 3, a memory cell 50 includes N-channel MOS transistors 52 to 58, P-channel TFTs 60, 62, and storage nodes 64, 66.

In memory cell 50, a flip-flop implemented by cross-connecting an inverter constituted of P-channel TFT 60 and N-channel MOS transistor 52 to an inverter constituted of P-channel TFT 62 and N-channel MOS transistor 54 is connected to bit lines 68A, 68B via two N-channel MOS transistors 56, 58 implementing access transistors.

In the SRAM, data stored in the flip-flop constituting a memory cell is bistable, and such a state is maintained so long as internal power supply voltage int.Vcc is supplied. In addition, the SRAM does not require a refreshing operation as the DRAM, thereby attaining low current consumption. Therefore, when semiconductor device 10A is backed up by the battery during stand-by so as to hold storage data, a storage state of the SRAM can be maintained for a long period of time.

Moreover, P-channel TFTs 60, 62 in memory cell 50 are configured in a manner similar to P-channel TFTs 32 to 36 in second reference voltage generation circuit 14A. In other words, second reference voltage generation circuit 14A is constituted of P-channel TFTs having a structure identical to that of the P-channel TFT in the memory cell of the SRAM. More specifically, each of P-channel TFTs 60, 62 of memory cell 50 and P-channel TFTs 32 to 36 in second reference voltage generation circuit 14A is composed of first polysilicon having the source, the drain and a channel formed, second polysilicon forming a gate electrode, and a gate insulating film provided between the first and second polysilicon. Vertical arrangement and film thickness of the first and second polysilicon as well as thickness of the gate insulating film are substantially equal among the P-channel TFTs.

As length and width of the first and second polysilicon depend on a resistance value of each component, the length and width may not necessarily be equal among the P-channel TFTs. If the first and second polysilicon can be designed to have an equal length and width in each P-channel TFT within a range tolerable in the specification, variation in manufacturing the P-channel TFTs can be suppressed.

As described above, an effect the same as in the first embodiment can be obtained according to semiconductor device 10A. In addition, by providing a battery for holding storage data in the SRAM during stand-by, a semiconductor device having the SRAM capable of holding the data for a long period of time can be implemented.

As second reference voltage generation circuit 14A is constituted of P-channel TFTs having a structure identical to that of the P-channel TFT in memory cell 50, P-channel TFTs 32 to 36 in second reference voltage generation circuit 14A can be formed in a process the same as that for P-channel TFTs 60, 62 in memory cell 50. That is, second reference voltage generation circuit 14A characterizing semiconductor device 10A can efficiently be obtained.

Third Embodiment

An overall configuration of a semiconductor device in a third embodiment is the same as that of semiconductor device 10A in the second embodiment shown in FIG. 2. Though the third embodiment also includes a memory unit storing data in internal circuit 18 as in the second embodiment, the memory unit in the third embodiment has a memory cell with a data holding characteristic during stand-by superior to that of the memory cell in the SRAM.

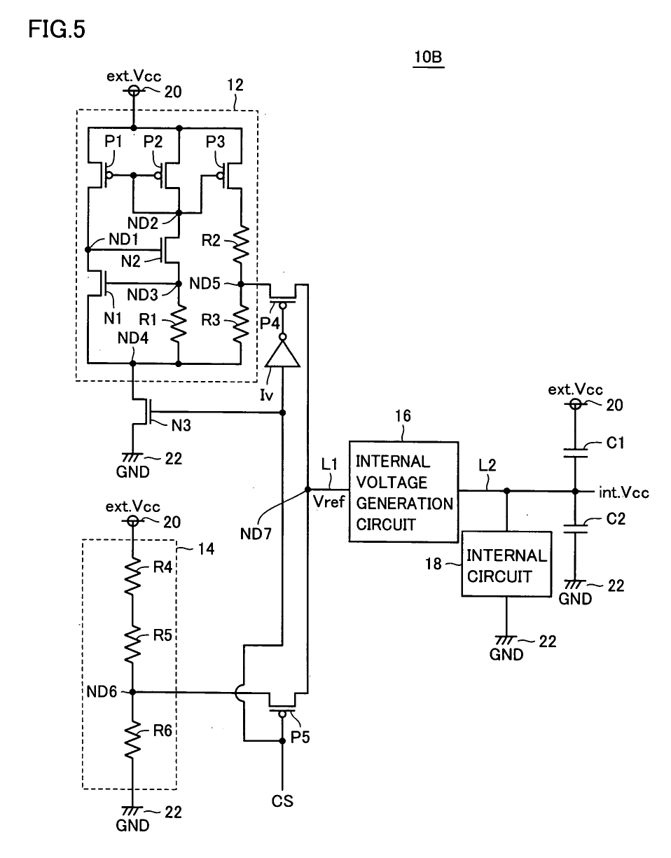

FIG. 4 is a circuit diagram showing a configuration of the memory cell in the memory unit contained in internal circuit 18 of the semiconductor device in the third embodiment.

Referring to FIG. 4, a memory cell 100 includes two adjacent data holding portions 102A, 102B storing one-bit data and inverted data thereof respectively. Data holding portion 102A is constituted of an N-channel MOS transistor 104A, a capacitor 106A, a charge compensation circuit 108A, and a storage node 110. Data holding portion 102B is constituted of an N-channel MOS transistor 104B, a capacitor 106B, a charge compensation circuit 108B, and a storage node 112.

N-channel MOS transistor 104A is connected between bit line 68A and storage node 110, and has the gate connected to a word line 70A. N-channel MOS transistor 104A is driven by word line 70A activated in data writing or data reading, and provides/receives charges between bit line 68A and storage node 110 in data writing or data reading.

Capacitor 106A is connected between storage node 110 and a cell plate 122, and stores data “1” or “0” depending on whether or not the charges are stored. Then, when a voltage corresponding to data “1” or “0” is applied to capacitor 106A from bit line 68A via N-channel MOS transistor 104A and storage node 110, capacitor 106A is charged/discharged for writing data.

Charge compensation circuit 108A is constituted of a P-channel TFT 114 and an N-channel MOS transistor 116. P-channel TFT 114 is connected between a power supply node 72 to which internal power supply voltage int.Vcc is applied and storage node 110, and has the gate connected to storage node 112 paired up with storage node 110. N-channel MOS transistor 116 is connected between storage node 110 and a ground node 74 to which ground voltage GND is applied, and has the gate connected to storage node 112.

Charge compensation circuit 108A includes an inverter constituted of P-channel TFT 114 and N-channel MOS transistor 116. The inverter has an input node and an output node connected to storage nodes 112, 110 respectively.

Data holding portion 102B paired up with data holding portion 102A is basically configured in a manner the same as data holding portion 102A. N-channel MOS transistor 104B is connected between bit line 68B and storage node 112, and has the gate connected to a word line 70B. Capacitor 106B is connected between storage node 112 and cell plate 122, and stores charges corresponding to the inverted data of the data stored in capacitor 106A. Charge compensation circuit 108B includes an inverter constituted of a P-channel TFT 118 and an N-channel MOS transistor 120. The inverter has an input node and an output node connected to storage nodes 110, 112 respectively.

An operation of the memory cell will be described, assuming that a state in which capacitor 106A is charged while capacitor 106B is not charged corresponds to data “1”. When data “1” is written, bit lines 68A, 68B are precharged to internal power supply voltage int.Vcc and ground voltage GND respectively, and word lines 70A, 70B are activated. Accordingly, N-channel MOS transistors 104A, 104B turn ON, and internal power supply voltage int.Vcc is applied to capacitor 106A from bit line 68A via N-channel MOS transistor 104A and storage node 110, for charging capacitor 106A. On the other hand, ground voltage GND is applied to capacitor 106B from bit line 68B via N-channel MOS transistor 104B and storage node 112, for releasing charges from capacitor 106B to bit line 68B.

When data “1” is written, storage nodes 110, 112 attain H level and L level respectively, and P-channel TFTs 114, 118 and N-channel MOS transistors 116, 120 turn ON, OFF, OFF, and ON respectively. Here, P-channel TFTs 114, 118 have an ON current and an OFF current of approximately 1×10⁻¹¹ A and 1×10⁻¹³ A respectively, while a leakage current from storage nodes 110, 112 due to the OFF current of a bulk transistor is of approximately 1×10⁻¹⁵ A. That is, the ON current of P-channel TFT 114 is larger than the leakage current from storage node 110 by four orders of magnitude. Therefore, after data “1” is written, storage node 110 and capacitor 106A connected thereto can be charged from power supply node 72 by means of P-channel TFT 114. Meanwhile, charges in storage node 112 and capacitor 106B connected thereto are released by N-channel MOS transistor 120 that has turned ON. Therefore, storage node 112 is held at ground voltage GND level.

Storage nodes 110, 112 thus attain internal power supply voltage int.Vcc and ground voltage GND level respectively. Such voltage states are latched by cooperation of charge compensation circuits 108A, 108, and thereafter, no refreshing operation is performed. Therefore, written data “1” is held.

It is noted that each current value described above is given solely for indicating the order thereof, without limited thereto.

In data reading, bit lines 68A, 68B are precharged to a voltage int.Vcc/2 in advance, and thereafter, word lines 70A, 70B are activated. Then, N-channel MOS transistors 104A, 104B both turn ON. In accordance with charged state of capacitors 106A, 106B, a potential of bit line 68A is slightly raised, while a potential of bit line 68B is slightly lowered. This voltage change is compared by a not-shown sense amplifier, and voltages of bit lines 68A, 68B are amplified to internal power supply voltage int.Vcc and ground voltage GND respectively. This voltage level of bit line 68A corresponds to data “1”.

Data holding portions 102A, 102B are the same in their circuit configuration. Accordingly, each operation for writing, holding and reading of data “0” is the same as that described above, except that operations that have been performed by data holding portions 102A, 102B respectively are now simply switched therebetween. Therefore, description thereof will not be repeated.

As described above, data holding portions 102A, 102B both include a pair of capacitors and an N-channel MOS transistor as basic components as in the DRAM, and charges of the capacitors are compensated by the charge compensation circuit, thereby not requiring a refreshing operation. In addition, as a stand-by current is determined by the P-channel TFT contained in the charge compensation circuit, the stand-by current in the memory cell is equivalent to that in the SRAM, i.e., small. Therefore, when the data is held with back-up by the battery during stand-by, a storage state in the memory unit contained in internal circuit 18 can be maintained for a long period of time.

Here, as memory cell 100 stores the data by means of the capacitor, memory cell 100 has a property extremely resistant to a soft error caused by α ray or the like. The soft error caused by the α ray refers to such an error that electrons generated along a range of the α ray incident on a substrate are collected in an N-type diffusion region and collected electrons cause data inversion. In memory cell 100, however, capacitors 106A, 106B are separately provided on N-channel MOS transistors 104A, 104B, 116, 120 constituting memory cell 100 for holding charges.

In addition, as an amount of charges held by capacitors 106A, 106B is larger than an amount of electrons collected by the α ray in memory cell 100, data inversion by the collected electrons is not caused. Therefore, according to memory cell 100, the soft error during stand-by does not take place, and non-volatile data holding is enabled.

Moreover, P-channel TFTs 114, 118 in memory cell 100 have a structure the same as that of P-channel TFTs 32 to 36 in second reference voltage generation circuit 14A. In other words, as described in the second embodiment, second reference voltage generation circuit 14A is constituted of the P-channel TFTs having a structure identical to that of the P-channel TFT in memory cell 100. Therefore, P-channel TFTs 32 to 36 in second reference voltage generation circuit 14A can be formed in a process the same as that for P-channel TFTs 114, 118 in memory cell 100, whereby second reference voltage generation circuit 14A can efficiently be obtained.

As described above, according to the semiconductor device in the third embodiment, an effect the same as in the first embodiment is obtained. In addition, by providing the battery for holding the data in the memory unit during stand-by, a semiconductor device having a pseudo non-volatile memory capable of holding the data in a more stable manner for a longer period of time than semiconductor device 10A in the second embodiment can be implemented.

Fourth Embodiment

Though first reference voltage generation circuit 12 and second reference voltage generation circuit 14 are connected in series in the first embodiment, these circuits are connected in parallel in a fourth embodiment and one of these circuits is electrically connected to reference voltage line L1 depending on the operation mode.

FIG. 5 is a circuit diagram showing a configuration of a main portion of a semiconductor device 10B in the fourth embodiment of the present invention.

Referring to FIG. 5, semiconductor device 10B further includes a P-channel MOS transistor P5 and a node ND 7 connected to P-channel MOS transistors P4, P5 in addition to the configuration of semiconductor device 10 in the first embodiment. Second reference voltage generation circuit 14 is connected in parallel to first reference voltage generation circuit 12 with P-channel MOS transistor P5 interposed.

P-channel MOS transistor P5 is connected between node ND 7 and node ND6 of second reference voltage generation circuit 14, and receives control signal CS at its gate. As the configuration is otherwise the same as that of semiconductor device 10 in the first embodiment, description thereof will not be repeated.

Here, P-channel MOS transistors P4, P5 implement a “switching circuit”.

In semiconductor device 10B, when control signal CS attains H level, N-channel MOS transistor N3 and P-channel MOS transistor P4 turn ON, while P-channel MOS transistor P5 turns OFF. Then, first reference voltage generation circuit 12 is activated, and reference voltage Vref generated by first reference voltage generation circuit 12 is output to reference voltage line L1. Second reference voltage generation circuit 14 is electrically disconnected from reference voltage line L1.

Internal voltage generation circuit 16 generates internal power supply voltage int.Vcc based on reference voltage Vref generated by first reference voltage generation circuit 12, and each circuit contained in internal circuit 18 operates by receiving internal power supply voltage int.Vcc.

On the other hand, when control signal CS attains L level, N-channel MOS transistor N3 and P-channel MOS transistor P4 turn OFF, while P-channel MOS transistor P5 turns ON. Then, first reference voltage generation circuit 12 is inactivated, and through current Ip1 does not flow through first reference voltage generation circuit 12. First reference voltage generation circuit 12 is electrically disconnected from reference voltage line L1.

Second reference voltage generation circuit 14 is electrically connected to reference voltage line L1, and reference voltage Vref generated by second reference voltage generation circuit 14 is supplied to internal voltage generation circuit 16. Internal voltage generation circuit 16 generates internal power supply voltage int.Vcc based on reference voltage Vref generated by second reference voltage generation circuit 14, and supplies generated internal power supply voltage int.Vcc to internal circuit 18.

First and second reference voltage generation circuits 12, 14 are switched in semiconductor device 10B in the fourth embodiment for the following reasons. When a difference in value between through current Ip1 of first reference voltage generation circuit 12 and through current Ip2 of second reference voltage generation circuit 14 is small, a difference of current drivability between first and second reference voltage generation circuits 12, 14 is also small. In particular, when the difference in value between through currents Ip1, Ip2 is in a range of one order of magnitude, an output from first reference voltage generation circuit 12 is affected by an output from second reference voltage generation circuit 14 during operation under the configuration as the first embodiment shown in FIG. 1. On the other hand, as semiconductor device 10B includes a switching circuit capable of switching between first and second reference voltage generation circuits 12, 14, interference of outputs from first and second reference voltage generation circuits 12, 14 with each other can be avoided.

Though not shown, an N-channel MOS transistor receiving an inverted signal of control signal CS at its gate or a P-channel MOS transistor receiving control signal CS at its gate may be provided between second reference voltage generation circuit 14 and ground node 22. With such a configuration, though through current Ip2 in second reference voltage generation circuit 14 is small, current consumption in second reference voltage generation circuit 14 during operation can be reduced to 0.

As described above, an effect the same as in the first embodiment can be obtained also according to the fourth embodiment. Moreover, interference of the outputs from first and second reference voltage generation circuits 12, 14 with each other can be avoided.

Fifth Embodiment

In a fifth embodiment, the first reference voltage generation circuit and the second reference voltage generation circuit are connected in parallel, and the second reference voltage generation circuit is constituted of TFTs.

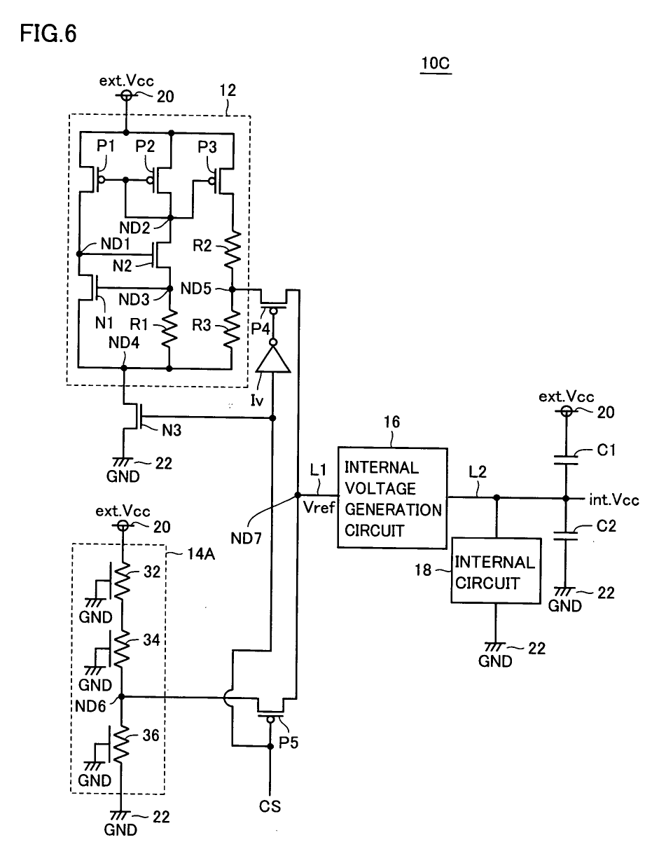

FIG. 6 is a circuit diagram showing a configuration of a main portion of a semiconductor device 10C in the fifth embodiment of the present invention.

Referring to FIG. 6, semiconductor device 10C includes second reference voltage generation circuit 14A instead of second reference voltage generation circuit 14 in the configuration of semiconductor device 10B in the fourth embodiment. As the configuration of second reference voltage generation circuit 14A has already been discussed in the second embodiment, description thereof will not be repeated.

Semiconductor device 10C operates in a manner similar to semiconductor device 10B in the fourth embodiment. Therefore, semiconductor device 10C also includes a switching circuit capable of switching between first and second reference voltage generation circuits 12, 14A as in semiconductor device 10B, so that interference of outputs from first and second reference voltage generation circuits 12, 14A with each other can be avoided.

It is noted that internal circuit 18 in semiconductor device 10C may also include a TFT load type SRAM, as described in the second embodiment. In addition, internal circuit 18 may include a memory unit described in the third embodiment instead of the TFT load type SRAM. In this case, a P-channel TFT of the structure the same as that of the P-channel TFT in the memory cell of the memory unit or the SRAM is used to constitute second reference voltage generation circuit 14A, thereby efficiently constituting second reference voltage generation circuit 14A.

As described above, an effect the same as in the first embodiment can be obtained also according to the fifth embodiment. Moreover, interference of the outputs from first and second reference voltage generation circuits 12, 14A with each other can be avoided.

Here, the number of resistors in second reference voltage generation circuit 14 in the first and fourth embodiments and the number of TFTs in second reference voltage generation circuit 14A in the second, third and firth embodiments above are not limited to these examples. An appropriate number of resistors and TFTs as well as appropriate resistance values thereof are determined based on reference voltage Vref and a tolerable range of through current Ip2 during stand-by.

In addition, first reference voltage generation circuit 12 in each embodiment described above is not limited to a voltage generation circuit of threshold voltage reference type. For example, a generally known conventional reference voltage generation circuit such as of a diode-connection type, a bandgap reference type or the like may be used.

Moreover, though reference voltage Vref generated by first and second reference voltage generation circuits has been used as a reference voltage of internal voltage generation circuit 16 in each embodiment above, application of reference voltage Vref is not limited to this example. In a semiconductor device, reference voltage Vref is used by a variety of circuits, and reference voltage Vref generated by the first and second reference voltage generation circuits can be used in each of these circuits.

Furthermore, though TFTs constituting second reference voltage generation circuit 14A have been of P-channel type in the second, third and firth embodiments, they may be of N-channel type. In this case as well, through current Ip2 in second reference voltage generation circuit 14A can extremely be small.

P-channel MOS transistors P4, P5 are provided between first reference voltage generation circuit 12 and reference power supply line L1 and between second reference voltage generation circuit 14, 14A and reference power supply line L1 respectively in each embodiment above. Alternatively, an N-channel MOS transistor may be provided. In such a case, it is necessary to boost the gate voltage of the N-channel MOS transistor so that voltage drop by a value of the threshold voltage does not take place in the N-channel MOS transistor.

In addition, internal circuit 18 may include a high resistance load type SRAM obtained by replacing the P-channel TFT with a high resistance in the configuration of memory cell 50 shown in FIG. 3 in the first and fourth embodiments including second reference voltage generation circuit 14 constituted of resistors R4 to R6. Alternatively, internal circuit 18 may include a memory unit constituted of memory cells obtained by replacing the P-channel TFT with a high resistance in the configuration of memory cell 100 shown in FIG. 4. The high resistance load type SRAM and the memory unit constituted of the memory cells obtained by replacing the P-channel TFT with a high resistance in the configuration of memory cell 100 can also perform an operation equivalent to the TFT load type SRAM and the storage unit constituted of memory cells 100 respectively. Therefore, when second reference voltage generation circuit 14 is configured using the same high resistance as that used in the memory cell of the memory unit or the SRAM, second reference voltage generation circuit 14 can efficiently be configured.

Though P-channel MOS transistor P4 is provided in order to connect or disconnect first reference voltage generation circuit 12 to/from reference voltage line L1 in each embodiment described above, a transfer gate implemented by connecting in parallel a P-channel MOS transistor and an N-channel MOS transistor may be provided instead of P-channel MOS transistor P4. Then, a voltage of a wider range can be transmitted from first reference voltage generation circuit 12 to reference voltage line L1.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device, comprising:
a first reference voltage generation circuit inactivated during stand-by and generating a prescribed reference voltage and outputting the generated reference voltage to a reference voltage line during operation which means non stand-by; and
a second reference voltage generation circuit generating said reference voltage during said stand-by using a through current smaller than in said first reference voltage generation circuit and outputting the generated reference voltage to said reference voltage line.

2. The semiconductor device according to claim 1, wherein
said second reference voltage generation circuit is always electrically connected to said reference voltage line and always activated.

3. The semiconductor device according to claim 1, wherein
said second reference voltage generation circuit includes
at least one first resistance element composed of polysilicon and connected in series between a first node to which a first power supply voltage higher than said reference voltage is applied and a second node at which said reference voltage is generated, and
at least one second resistance element composed of said polysilicon and connected in series between said second node and a third node to which a second power supply voltage lower than said reference voltage is applied, and
each of said at least one first resistance element and said at least one second resistance element includes a thin film transistor in an ON state.

4. The semiconductor device according to claim 1, further comprising a memory circuit including a plurality of memory cells storing data, wherein
said second reference voltage generation circuit includes
at least one first resistance element composed of polysilicon and connected in series between a first node to which a first power supply voltage higher than said reference voltage is applied and a second node at which said reference voltage is generated, and
at least one second resistance element composed of said polysilicon and connected in series between said second node and a third node to which a second power supply voltage lower than said reference voltage is applied,
each of said plurality of memory cells includes a third resistance element composed of said polysilicon, and
each of said at least one first resistance element, said at least one second resistance element and said third resistance element has an identical configuration.

5. The semiconductor device according to claim 1, further comprising a switching circuit electrically connecting said first reference voltage generation circuit to said reference voltage line during said operation and electrically connecting said second reference voltage generation circuit to said reference voltage line during said stand-by.

6. The semiconductor device according to claim 1, further comprising:
an internal voltage generation circuit generating an internal power supply voltage of the semiconductor device using said reference voltage;
a first capacitive element connected between a first node to which a first power supply voltage higher than said reference voltage is applied and an internal power supply line to which said internal power supply voltage generated by said internal voltage generation circuit is output; and
a second capacitive element connected between said internal power supply line and a second node to which a second power supply voltage lower than said reference voltage is applied.
